(19) United States
(12) Patent Application Publication
(10) Pub. No.: US 2022/0336555 A1
(43) Pub. Date: Oct. 20, 2022

(54) DISPLAY SUBSTRATE, DISPLAY PANEL AND DISPLAY DEVICE

(71) Applicants: Chengdu BOE Optoelectronics Technology Co., Ltd., Chengdu, Sichuan Province (CN); BOE Technology Group Co., Ltd., Beijing (CN)

(72) Inventors: Benlian WANG, Beijing (CN); Yao HUANG, Beijing (CN); Yue LONG, Beijing (CN); Tianyi CHENG, Beijing (CN); Weiyun HUANG, Beijing (CN)

(21) Appl. No.: 17/418,085

(22) PCT Filed: Sep. 22, 2020
(86) PCT No.: PCT/CN2020/116858

§ 371 Date: Jun. 24, 2021

(51) Int. Cl. H01L 27/32

(52) U.S. Cl. CPC H01L 27/3258; H01L 27/3272

(57) ABSTRACT

The present disclosure provides a display substrate, display panel and display device. The display substrate includes: a base substrate; a low temperature poly-silicon thin film transistor located on the base substrate and including a first active layer and a first gate electrode disposed in a stacked manner on the base substrate; an oxide thin film transistor located on the base substrate and including a second active layer located on a side of a layer with the first gate electrode facing away from the base substrate; a first gate insulating layer located between the first active layer and the layer with the first gate electrode and including a hydrogen-containing insulating layer; and a first interlayer insulating layer located between the layer with the first gate electrode and the second active layer and including a hydrogen blocking material layer.

### FIELD

The present disclosure relates to the field of display, in particular to a display substrate, a display panel and a display device.

### BACKGROUND

As the display technology continues to evolve, there are increasingly high demands for resolution, power consumption, and image quality of display products. In order to meet these demands, a Low Temperature Polycrystalline Oxide (LTPO) technology is usually used now for fabricating a pixel driving circuit in a driving backplane of a display product. This LTPO technology is: simultaneously utilizing a low-temperature poly-silicon thin film transistor (LTPS TFT) and a metal oxide thin film transistor (Oxide TFT) as functional tubes in the pixel driving circuit. As the low-temperature poly-silicon thin film transistor has high mobility and can speed up charging of pixel capacitors and the metal oxide thin film transistor has lower leakage current, the advantages of these two transistors are combined to facilitate the development of the display products with high resolution, low power consumption and high image quality.

### SUMMARY

In a first aspect, embodiments of the present disclosure provide a display substrate, including:

a base substrate;

a low temperature poly-silicon thin film transistor located on the base substrate and including a first active layer and a first gate electrode disposed in a stacked manner on the base substrate;

an oxide thin film transistor located on the base substrate and including a second active layer located on a side of a layer with the first gate electrode facing away from the base substrate;

a first gate insulating layer located between the first active layer and the layer with the first gate electrode and including a hydrogen-containing insulating layer; and

a first interlayer insulating layer located between the layer with the first gate electrode and the second active layer and including a hydrogen blocking material layer.

Optionally, in the display substrate provided by the embodiments of the present disclosure, the first gate insulating layer includes a silicon oxide layer, and a silicon nitride layer located between the silicon oxide layer and the layer with the first gate electrode.

Optionally, in the display substrate provided by the embodiments of the present disclosure, the first interlayer insulating layer includes a silicon oxide layer.

Optionally, the display substrate provided by the embodiments of the present disclosure further includes a metal portion disposed on the same layer as the first gate electrode; and where an overlap area of an orthographic projection of the metal portion on the base substrate and an orthographic projection of the first active layer on the base substrate is S1, and an overlap area of the orthographic projection of the metal portion on the base substrate and an orthographic projection of the second active layer on the base substrate is S2, where S2 is greater than S1.

Optionally, in the display substrate provided by the embodiments of the present disclosure, the first interlayer insulating layer includes: a first silicon oxide layer and a second silicon oxide layer disposed in a stacked manner.

Optionally, the display substrate provided by the embodiments of the present disclosure further includes: a metal portion located between the first silicon oxide layer and the second silicon oxide layer; where an overlap area of an orthographic projection of the metal portion on the base substrate and an orthographic projection of the first active layer on the base substrate is S1, and the overlap area of the orthographic projection of the metal portion on the base substrate and an orthographic projection of the second active layer on the base substrate is S2, where S2 is greater than S1.

Optionally, in the display substrate provided by the embodiments of the present disclosure, the metal portion is a second gate electrode of the oxide thin film transistor.

Optionally, in the display substrate provided by the embodiments of the present disclosure, the metal portion is a light shielding layer, where an orthographic projection of the light shielding layer on the base substrate covers the orthographic projection of the second active layer on the base substrate.

Optionally, in the display substrate provided by the embodiments of the present disclosure, the low temperature poly-silicon thin film transistor further includes: a first source electrode and a first drain electrode located on a side of the layer with the first gate electrode facing away from the first active layer, and the first source electrode and the first drain electrode are electrically connected with the first active layer respectively; and the oxide thin film transistor further includes: a third gate electrode located on a side of the second active layer facing away from the first interlayer insulating layer, as well as a second source electrode and a second drain electrode located on a side of a layer with the third gate electrode facing away from the second active layer; where the second source electrode and the second drain electrode are electrically connected with the second active layer respectively, and the second source electrode and the second drain electrode are disposed on the same layer as the first source electrode and the first drain electrode.

Optionally, the display substrate provided by the embodiments of the present disclosure further includes: a second gate insulating layer located between the second active layer and the layer with the third gate electrode and formed from silicon oxide, and a second interlayer insulating layer located between the layer with the third gate electrode and the layer with the second source electrode and the second drain electrode.

Optionally, in the display substrate provided by the embodiments of the present disclosure, the second interlayer insulating layer includes a silicon oxide layer, or includes a silicon oxide layer and a silicon nitride layer arranged in a stacked manner.

Optionally, the display substrate provided by the embodiments of the present disclosure further includes: a barrier layer located between the base substrate and the first active layer, and a buffer layer located between the barrier layer and the first active layer.

In a second aspect, embodiments of the present disclosure also provide a display panel including the display substrate described above.

In a third aspect, embodiments of the present disclosure also provide a display device including the display panel described above.

### BRIEF DESCRIPTION OF THE DRAWINGS

FIG. 1 shows a schematic structural diagram of a display substrate according to embodiments of the present disclosure.

FIG. 2 shows a schematic structural diagram of another display substrate according to embodiments of the present disclosure.

FIG. 3 shows a schematic structural diagram of another display substrate according to embodiments of the present disclosure.

FIG. 4 shows a schematic structural diagram of another display substrate according to embodiments of the present disclosure.

FIG. 5 shows a schematic structural diagram of another display substrate according to embodiments of the present disclosure.

FIG. 6 shows a schematic structural diagram of another display substrate according to embodiments of the present disclosure.

### DETAILED DESCRIPTION OF THE EMBODIMENTS

In order to make the objectives, technical solutions and advantages of embodiments of the present disclosure clearer, the technical solutions of the embodiments of the present disclosure will be clearly and completely described below in conjunction with the accompanying drawings of the embodiments of the present disclosure. It needs to be noted that the sizes and shapes of the figures in the drawings do not reflect the true scale, but intend to merely illustrate the contents of the present disclosure. The same or similar reference numbers throughout refer to the same or similar elements or elements having the same or similar function. Clearly, the described embodiments are some, but not all, embodiments of the present disclosure. Based on the described embodiments of the present disclosure, all other embodiments obtained by a person of ordinary skill in the art without inventive work fall within the protection scope of the present disclosure.

Unless otherwise defined, technical or scientific terms used herein are to be taken as commonly understood by a person of ordinary skill in the art to which this disclosure belongs. The terms “first”, “second” and the like, as used in the description and in the claims, do not denote any order, quantity, or importance, but are merely used to distinguish one component from another. The word “including” or “containing” and the like means that elements or items preceding the word appear to encompass elements or items and equivalents thereof listed after the word without excluding other elements or items. “Inner”, “outer”, “upper”, “lower” and the like are only used to indicate relative position relationships, which may change accordingly when the absolute position of the object being described changes.

In the process for fabricating a low temperature poly-silicon thin film transistor, a large amount of hydrogen needs to be introduced during fabrication of a first active layer of the low temperature poly-silicon thin film transistor, a variety of high temperature processes are also included during the entire fabrication of a driving backplane, when subjected to these high temperature processes, the hydrogen tends to diffuse into a hydrogen-sensitive second active layer included in a metal oxide thin film transistor, resulting in reduced reliability of the driving backplane and even direct failure of the produced driving backplane.

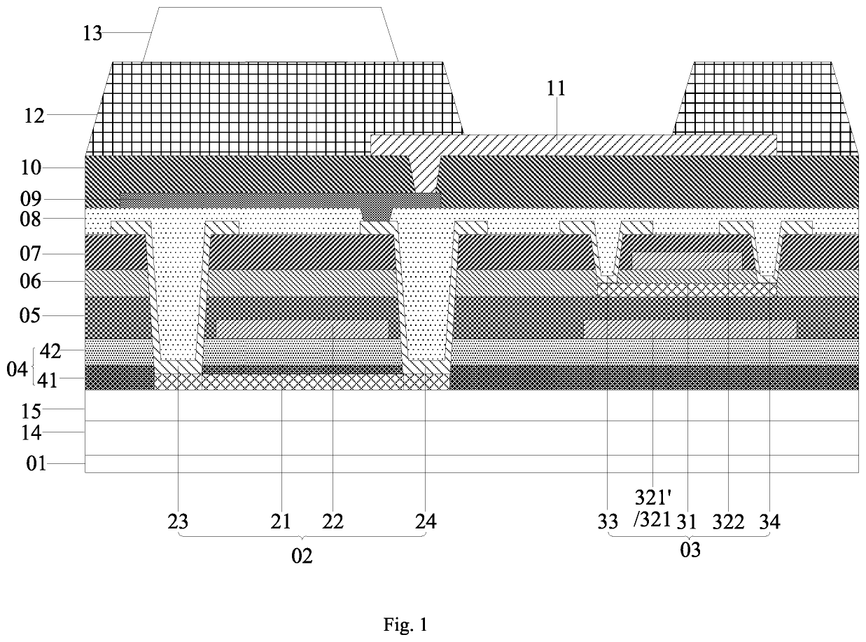

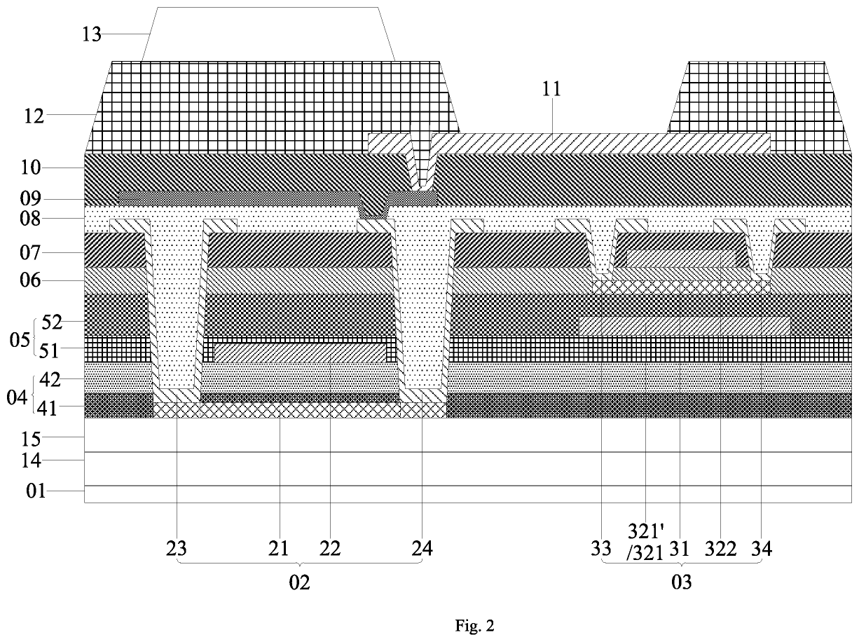

In response to the above problems existing in the related art, embodiments of the present disclosure provide a display substrate, as shown in FIGS. 1 and 2, including:

a base substrate 01;

a low temperature poly-silicon thin film transistor 02 located on the base substrate 01 and including a first active layer 21 and a first gate electrode 22 disposed in a stacked manner on the base substrate 01;

an oxide thin film transistor 03 located on the base substrate 01 and including a second active layer 31 located on a side of a layer with the first gate electrode 22 facing away from the base substrate 01;

a first gate insulating layer 04 located between the first active layer 21 and the layer with the first gate electrode 22 and including a hydrogen-containing insulating layer; and

a first interlayer insulating layer 05 located between the layer with the first gate electrode 22 and the second active layer 32 and including a hydrogen blocking material layer.

By disposing the first gate insulating layer 04 between the first active layer 21 and the layer with the first gate electrode 22, and disposing the first interlayer insulating layer 05 between the layer with the first gate electrode 22 and the second active layer 31, the first gate insulating layer 04 including the hydrogen-containing insulating layer may provide hydrogen for the first active layer 21, the first interlayer insulating layer 05 including the hydrogen blocking material layer may prevent the hydrogen from diffusing to the second active layer 31, thus the stability of the low temperature poly-silicon thin film transistor 02 and the oxide thin film transistor 03 is better, and the reliability of the fabricated display substrate is well ensured.

It should be noted that an active layer generally includes a channel region, as well as a source contact region and a drain contact region located on two sides of the channel region respectively. In the present disclosure, the active layer specifically refers to the channel region. In addition, a poly-silicon material has high mobility, low energy consumption, and high reliability. Accordingly, the low temperature poly-silicon thin film transistor 02 may be applied to a gate driver and/or a multiplexer (MUX) for driving one or more driving elements of a thin film transistor of a display device. Preferably, the low temperature poly-silicon thin film transistor 02 may be applied as a driving transistor within a pixel circuit of an organic light emitting display device. A band gap of an oxide semiconductor material is larger than that of a silicon material, thus electrons cannot pass through the band gap in an off-state, and the cut-off current is low. Thus, the oxide thin film transistor 03 is suitable for thin film transistors that remain on for a short time and off for a long time. Furthermore, since the cut-off current is low, a size of an auxiliary capacitor may be reduced. Therefore, the oxide thin film transistor 03 is suitable for a high-resolution-ratio display element. Exemplarily, the oxide thin film transistor 03 may be applied as a switching transistor within the pixel circuit of the organic light emitting display device. Besides, the base substrate 01 may be a substrate of a flexible material such as polyimide (PI) or a substrate of a rigid material such as glass, which is not limited here.

Optionally, in the display substrate provided by the embodiments of the present disclosure, as shown in FIGS. 1 and 2, the first gate insulating layer 04 includes: a silicon oxide (SiOx) layer 41, and a silicon nitride (SiNx) layer 42 located between the silicon oxide layer 41 and the layer with the first gate electrode 22. The silicon nitride layer 41 is a hydrogen-rich material and may provide the hydrogen for the first active layer 21. Optionally, the low temperature poly-silicon thin film transistor 02 has high mobility typically. Thus, in order to increase the mobility of the low temperature poly-silicon thin film transistor 02, preferably, a significant amount of hydrogen can be injected into the first active layer 21 by increasing a thickness of the silicon nitride layer 42 during hydroprocessing. Considering that there is a threshold thickness at which the amount of hydrogen injected into the first active layer 21 by hydroprocessing is saturated, during specific implementation, a thickness of the silicon nitride layer 42 may be suitably selected according to a target mobility and the threshold thickness of the low temperature poly-silicon thin film transistor 02. Optionally, the thickness of the silicon nitride layer 42 may be greater than or equal to 200 Å and less than or equal to 3,000 Å, specifically e.g. 200 Å, 300 Å, 400 Å, 500 Å, 600 Å, 700 Å, 800 Å, 900 Å, 1,000 Å, 1,100 Å, 1,200 Å, 1,300 Å, 1,400 Å, 1,500 Å, 1,600 Å, 1,700 Å, 1,800 Å, 1,900 Å, 2,000 Å, 2,100 Å, 2,200 Å, 2,300 Å, 2,400 Å, 2,500 Å, 2,600 Å, 2,700 Å, 2,800 Å, 2,900 Å, 3,000 Å, etc. Additionally, hydroprocessing of the first active layer 21 can be accomplished by diffusing hydrogen contained in the silicon nitride layer 42 into the first active layer 21 by thermal treatment to fill vacancies of poly-silicon. Further optionally, a thickness of the silicon oxide layer 41 may be greater than or equal to 200 Å and less than or equal to 3,000 Å, specifically e.g. 200 Å, 300 Å, 400 Å, 500 Å, 600 Å, 700 Å, 800 Å, 900 Å, 1,000 Å, 1,100 Å, 1,200 Å, 1,300 Å, 1,400 Å, 1,500 Å, 1,600 Å, 1,700 Å, 1,800 Å, 1,900 Å, 2,000 Å, 2,100 Å, 2,200 Å, 2,300 Å, 2,400 Å, 2,500 Å, 2,600 Å, 2,700 Å, 2,800 Å, 2,900 Å, 3,000 Å, etc.

Optionally, in the display substrate provided by the embodiments of the present disclosure, as shown in FIGS. 1 and 2, the first interlayer insulating layer 05 may be a single-layer or a double-layer silicon oxide (SiOx) layer, specifically, FIG. 1 shows a single-layer silicon oxide layer and FIG. 2 shows a first silicon oxide layer 51 and a second silicon oxide layer 52 disposed in a stacked manner. Optionally, a thickness of the single-layer silicon oxide layer included in the first interlayer insulating layer 05 in FIG. 1 may be greater than or equal to 3,000 Å and less than or equal to 6,000 Å, illustratively e.g. 3,000 Å, 3,500 Å, 4,000 Å, 4,500 Å, 5,000 Å, 5,500 Å, 6,000 Å, etc. A thickness of the first silicon oxide layer 51 included in the first interlayer insulating layer 05 in FIG. 2 may be greater than or equal to 500 Å and less than or equal to 3,000 Å, e.g. 500 Å, 600 Å, 700 Å, 800 Å, 900 Å, 1,000 Å, 1,100 Å, 1,200 Å, 1,300 Å, 1,400 Å, 1,500 Å, 1,600 Å, 1,700 Å, 1,800 Å, 1,900 Å, 2,000 Å, 2,100 Å, 2,200 Å, 2,300 Å, 2,400 Å, 2,500 Å, 2,600 Å, 2,700 Å, 2,800 Å, 2,900 Å, 3,000 Å, etc. A thickness of the second silicon oxide layer 52 included in the first interlayer insulating layer 05 may be greater than or equal to 3,000 Å and less than or equal to 6,000 Å, e.g. 3,000 Å, 3,500 Å, 4,000 Å, 4,500 Å, 5,000 Å, 5,500 Å, 6,000 Å, etc.

Optionally, a material of the second active layer 31 may be indium gallium zinc oxide (IGZO), etc. The indium gallium zinc oxide is generally deposited at high temperatures, which can increase its crystallization efficiency and reduce oxygen vacancies in the second active layer 31. If there are a large number of oxygen vacancies in the second active layer 31, tunneling can occur, making the second active layer 31 conductive and the performance of the oxide thin film transistor ineffective. In the embodiments, after the first active layer 21 is hydrogen-supplemented with the silicon nitride layer 42, the amount of hydrogen contained in the silicon nitride layer 42 is reduced, while the silicon oxide layer contained in the first interlayer insulating layer 05 may effectively prevent the hydrogen from diffusing into the second active layer 31.

Optionally, in the display substrate provided by the embodiments of the present disclosure, as shown in FIG. 1, the display substrate further includes a metal portion 321′ disposed in the same layer as the first gate electrode 22. Of course, the metal portion 321′ may also be located between the first silicon oxide layer 51 and the second silicon oxide layer 52, as shown in FIG. 2. Optionally, an overlap area of an orthographic projection of the metal portion 321′ on the base substrate 01 and an orthographic projection of the first active layer 21 on base substrate 01 is S1, and an overlap area of the orthographic projection of the metal portion 321′ on the base substrate 01 and an orthographic projection of the second active layer 31 on the base substrate 01 is S2, where S2 is greater than S1, and optionally S1 is 0. Specifically, the metal portion 321′ may act as a second gate electrode 321 of the oxide thin film transistor 03 and also as a light shielding layer covering the second active layer 31 to block ambient light from entering the second active layer 31.

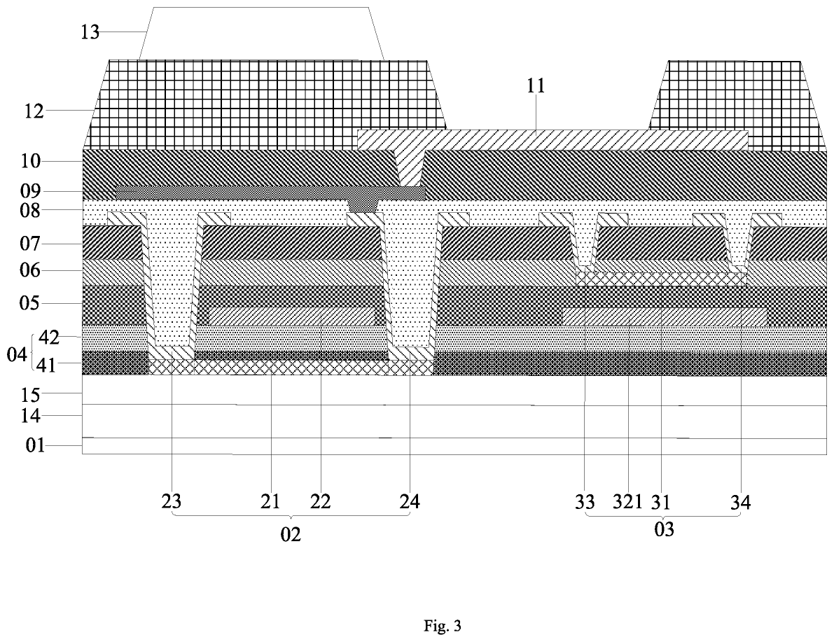

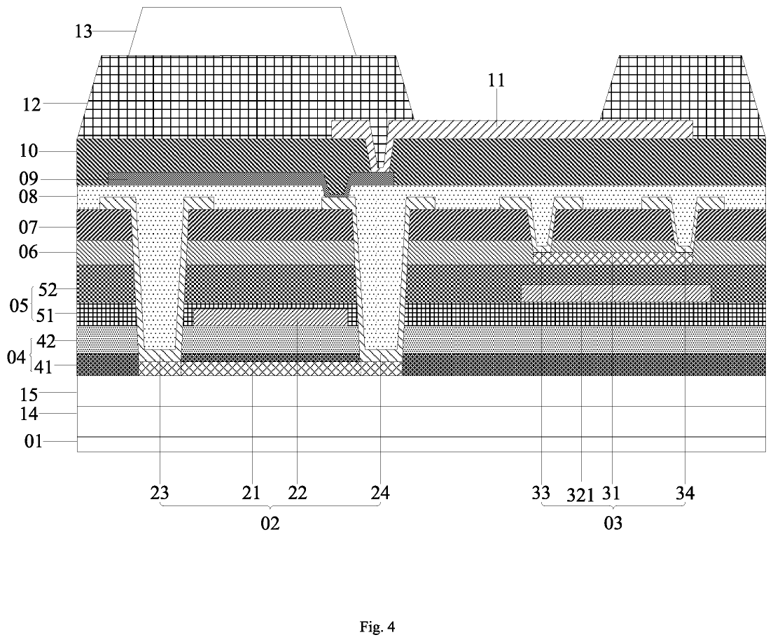

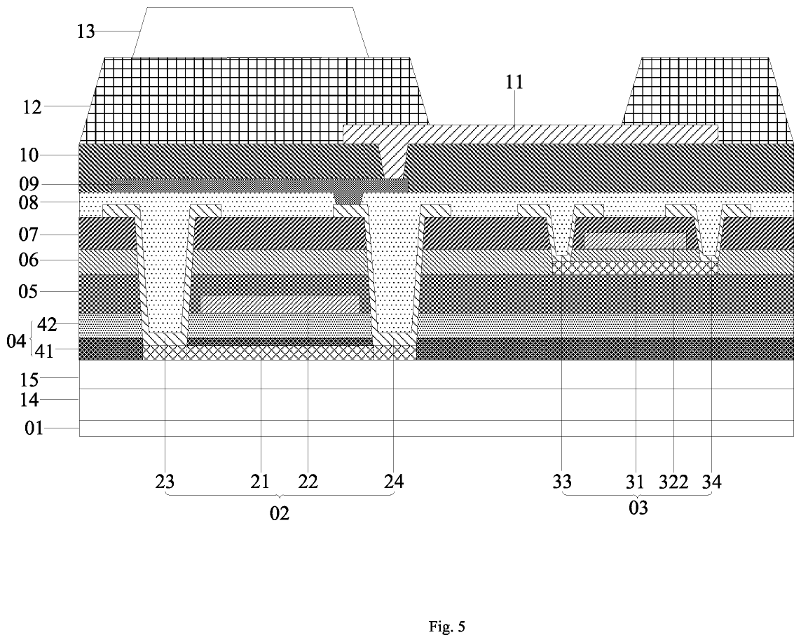

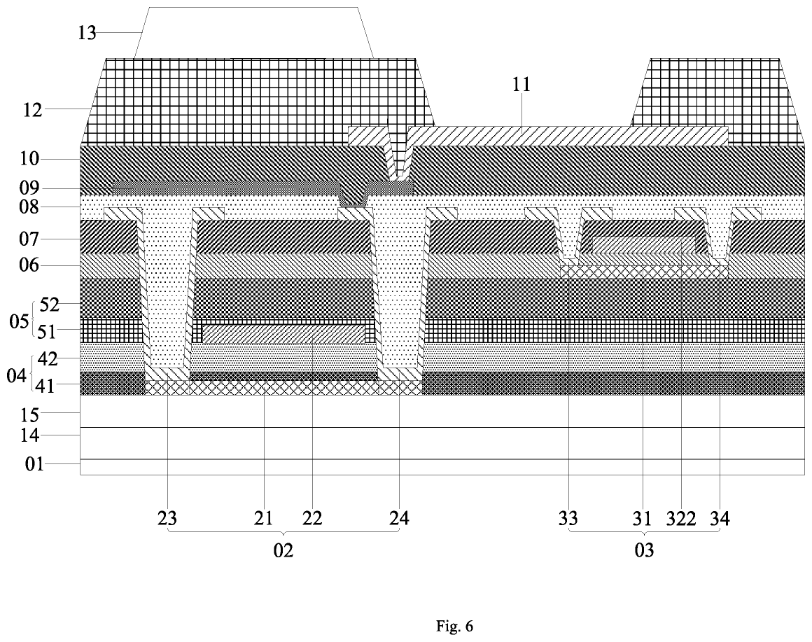

Note that when the metal portion 321′ serves as the second gate electrode 321 of the oxide thin film transistor 03, the oxide thin film transistor 03 may be a dual-gate thin film transistor (as shown in FIGS. 1 and 2), the metal portion 321′ may be loaded with the same scan signal as the third gate electrode 322, or the oxide thin film transistor 03 may be a bottom-gate thin film transistor (as shown in FIGS. 3 and 4), which is not limited here. When the metal portion 321′ serves as the light shielding layer that blocks the second active layer 31, the oxide thin film transistor 03 is a top-gate thin film transistor (as shown in FIGS. 1 and 2). Of course, it is also possible that no light shielding layer or second gate electrode 321 is arranged on the display substrate, the oxide thin film transistor 03 is a top-gate thin film transistor (as shown in FIGS. 5 and 6).

During specific implementation, a loaded potential of the light shielding layer may be the same as a loaded potential of a power line VDD (voltage drain drain), or be the same as a loaded potential of an initialization signal line or be the same as a loaded potential of a cathode (cathode potential VSS) or be the same as other fixed potentials. For example, the fixed potentials are in a range of −10 V to +10 V, or in a range of −5 V to +5 V, or in a range of −3 V to +3 V, or in a range of −1 V to +1 V, or in a range of −0.5 V to +0.5 V, or in a range of 0 V, or in a range of 0.1 V, or in a range of 10.1 V, or in a range of 0.2 V, or in a range of −0.2 V, or in a range of 0.3 V, or in a range of −0.3 V.

Specifically, the loaded potential of the light shielding layer 35 may be larger than the loaded potential of the cathode (cathode potential VSS) and smaller than the loaded potential of the power line VDD. Alternatively, the loaded potential of the light shielding layer 35 may be larger than the loaded potential of the initialization signal line and smaller than the loaded potential of the power line VDD.

Optionally, when the oxide thin film transistor 03 is a double-gate thin film transistor, as shown in FIGS. 1 and 2, the oxide thin film transistor 03 specifically may include: the second gate electrode 321 disposed on the same layer as the first gate electrode 22, the third gate electrode 322 located on a side of the second active layer 31 facing away from the first interlayer insulating layer 05, as well as a second source electrode 33 and a second drain electrode 34 located on a side of a layer with the third gate electrode 322 facing away from the second active layer 31. The second source electrode 33 and the second drain electrode 34 are electrically connected with the second active layer 31 respectively.

When the oxide thin film transistor 03 is a bottom-gate thin film transistor, as shown in FIGS. 3 and 4, the oxide thin film transistor 03 specifically may include: the second gate electrode 321 disposed on the same layer as the first gate electrode 22 as well as a second source electrode 33 and a second drain electrode 34 located on a side of the second active layer 31 facing away from the first interlayer insulating layer 05. The second source electrode 33 and the second drain electrode 34 are electrically connected with the second active layer 31 respectively.

When the oxide thin film transistor 03 is the top-gate thin film transistor, as shown in FIGS. 5 and 6, the oxide thin film transistor 03 specifically may include: the third gate electrode 322 located on a side of the second active layer 31 facing away from the first interlayer insulating layer 05, as well as the second source electrode 33 and the second drain electrode 34 located on a side of the layer with the third gate electrode 322 facing away from the second active layer 31. The second source electrode 33 and the second drain electrode 34 are electrically connected with the second active layer 31 respectively.

Preferably, when the oxide thin film transistor 03 is the top-gate thin film transistor, the influence of ambient light on the second active layer 31 can be avoided by arranging the metal portion 321′ as the light shielding layer, as shown in FIGS. 1 and 2. In addition, as shown in FIGS. 1 to 4, when the oxide thin film transistor 03 is the double-gate thin film transistor or the bottom-gate thin film transistor, the first interlayer insulating layer 05 is used as a gate insulating layer isolating the second gate electrode 321 from the second active layer 31 at the oxide thin film transistor 03.

Optionally, in the display substrate provided by the embodiments of the present disclosure, as shown in FIGS. 1 to 6, the low temperature poly-silicon thin film transistor 01, besides including the first active layer 21 and the first gate electrode 22, may further include a first source electrode 23 and a first drain electrode 24 located on a side of the layer with the first gate electrode 22 facing away from the first active layer 21, where the first source electrode 23 and the first drain electrode 24 are electrically connected with the first active layer 21 respectively, and the first source electrode 23 and the first drain electrode 24 are disposed on the same layer as the second source electrode 33 and the second drain electrode 34. Optionally, in the present disclosure, materials of the first gate electrode 22, the metal portion 321′, and the third gate electrode 322 may be molybdenum, aluminum, copper, titanium/aluminum/titanium, and other metals or alloys, which is not limited here.

Optionally, the display substrate provided by the embodiments of the present disclosure, as shown in FIGS. 1, 2, 5 and 6, may further include: a second gate insulating layer 06 formed from silicon oxide and located between the second active layer 31 and the layer with the third gate electrode 322, and a second interlayer insulating layer 07 located between the layer with the third gate electrode 322 and a layer with the second source electrode 33 and second drain electrode 34. The second gate insulating layer 06 formed from silicon oxide and in direct contact with the second active layer 31 can block diffusion of hydrogen to the second active layer 31 during subsequent formation of an inorganic encapsulation layer of silicon nitride. Optionally, the second interlayer insulating layer 07 may include a silicon oxide layer, or may further include a silicon oxide layer and a silicon nitride layer arranged sequentially in a stacked manner on the second gate insulating layer 06 in order to further improve the blocking effect on hydrogen during the subsequent formation of the inorganic encapsulating layer of silicon nitride. Optionally, other inorganic and/or organic layers such as oxide layers, nitride layers, polymer layers and the like may also be employed to form the second interlayer insulating layer 07 during specific implementation, which is not limited here.

In a specific embodiment, materials of the first interlayer insulating layer 05, the second gate insulating layer 06, and the second interlayer insulating layer 07 may be the same material, e.g. silicon oxide (SiOx). For example, oxygen contents of all the film layers may be the same or different. When the oxygen contents of the all the film layers are the same, or substantially the same, there is no distinct film layer boundary between all the film layers.

It should be noted that “substantially” in the present disclosure means that errors are within 10%.

Optionally, the display substrate provided by the embodiments of the present disclosure, as shown in FIGS. 1 to 6, may further include: a first flat layer 08, a contact electrode 09, a second flat layer 10, and an anode 11 located in sequence on a side of the layer with the second source electrode 33 and the second drain electrode 34 facing away from the base substrate 01. The contact electrode 09 is electrically connected with the first drain electrode 24 through a via-hole penetrating through the first flat layer 10, and the anode 11 is electrically connected with the contact electrode 09 through a via-hole penetrating through the second flat layer 10, such that the anode 11 is electrically connected to the corresponding first drain electrode 24 through the contact electrode 09. The arrangement of the contact electrode 09 equivalently and indirectly increases an contact area of the anode 11 with the corresponding first drain electrode 24, thereby effectively reducing contact resistance of the anode 11 with the corresponding first drain electrode 24. Optionally, materials of the first flat layer 08 and the second flat layer 10 may be an inorganic material such as silicon nitride or an organic material such as a polymer, as long as it is an insulating material layer that can function as planarization. A material of the contact electrode 09 may be a single-layer structure with molybdenum, aluminum, or copper, etc, or may be a three-layer structure with titanium/aluminum/titanium.

Optionally, the display substrate provided by the embodiments of the present disclosure, as shown in FIGS. 1 to 6, may further include: a pixel definition layer 12 and a spacer layer 13 located in sequence on a side of a layer with the anode 11 facing away from the base substrate 01.

An orthographic projection of the pixel definition layer 12 on the base substrate 01 and an orthographic projection of the anode 11 on the base substrate 01 overlap each other in edge. An orthographic projection of the spacer layer 13 on the base substrate 01 locates within the orthographic projection of the pixel definition layer 12 on the base substrate 01. The pixel definition layer 12 has a pixel opening at the anode 11 to define a sub-pixel area in which the anode 11 is located. The spacer layer 13 serves specifically to support a microcavity structure composed of the subsequent encapsulation layer and the pixel definition layer.

Optionally, the display substrate provided by the embodiments of the present disclosure, as shown in FIGS. 1 to 6, may further include: a barrier layer 14 located between the base substrate 01 and the first active layer 21, and a buffer layer 15 located between the barrier layer 14 and the first active layer 21, so that moisture or hydrogen in the environment and alkali metal elements discharged from the base substrate 01 are prevented from diffusing to the first active layer 21 through the barrier layer 14 and the buffer layer 15, and adhesion between the first active layer 21 and the base substrate 01 is improved. Optionally, the barrier layer 14 and the buffer layer 15 may be formed as a single layer by depositing either of silicon nitride or silicon oxide or as multiple layers by stacking silicon nitride and silicon oxide alternately. Additionally, the barrier layer 14 and the buffer layer 15 may also be formed as multiple layers by selecting any one of silicon nitride or silicon oxide having different characteristics (e.g. density, etc.). Exemplarily, the buffer layer 15 is a single-layer structure including silicon oxide, and the barrier layer 14 is of a four-layer structure including silicon oxide, silicon nitride, silicon oxide, and silicon nitride arranged in a stacked manner.

Based on the same inventive concept, embodiments of the present disclosure provide a display panel including the display substrate provided by the embodiments of the present disclosure. The display panel may be an organic light emitting diode (OLED) display panel, a quantum-dot light emitting diode (QLED) display panel. Other essential components of the display panel will be understood by those of ordinary skill in the art, are not described in detail herein and should not be taken as a limitation on the present disclosure. Since the principle of solving the problem of the display panel is similar to the principle of solving the problem of the display substrate described above, the implementation of the display panel provided by the embodiment of the present disclosure may refer to the implementation of the above-described display substrate provided by the embodiment of the present disclosure, and repetition is omitted.

On the basis of the same inventive concept, an embodiment of the present disclosure also provides a display device including the display panel provided by the embodiment of the present disclosure. The display device may be: a mobile phone, a tablet PC, a television, a display, a laptop, a digital photo frame, a navigator, a smart watch, a fitness band, a personal digital assistant, and any other display-enabled product or component. Other essential components of the display device will be understood by those of ordinary skill in the art, will not be described in detail herein and should not be taken as a limitation on the present disclosure. In addition, since the principle of solving the problem of the display device is similar to the principle of solving the problem of the display panel described above, the implementation of the display device may refer to the embodiment of the display panel described above, and repetition is omitted.

The embodiments of the present disclosure provide the display substrate, the display panel, and the display device. The display substrate includes: the base substrate; the low temperature poly-silicon thin film transistor located on the base substrate and including the first active layer and the first gate electrode disposed in a stacked manner on the base substrate; the oxide thin film transistor located on the base substrate and including the second active layer located on a side of the layer with the first gate electrode facing away from the base substrate; the first gate insulating layer located between the first active layer and the layer with the first gate electrode and including the hydrogen-containing insulating layer; and the first interlayer insulating layer located between the layer with the first gate electrode and the second active layer and including the hydrogen blocking material layer. By disposing the first gate insulating layer between the first active layer and the layer with the first gate electrode, and disposing the first interlayer insulating layer between the layer with the first gate electrode and the second active layer, the first gate insulating layer including the hydrogen-containing insulating layer can provide the hydrogen for the first active layer, and the first interlayer insulating layer including the hydrogen blocking material layer may prevent the hydrogen from diffusing to the second active layer, thus the stability of both the low temperature poly-silicon thin film transistor and the oxide thin film transistor is better, and the reliability of the fabricated display substrate is well ensured.

It will be apparent to those skilled in the art that various modifications and variations can be made to the embodiments of the present disclosure without departing from the spirit and scope of the embodiments of the preset disclosure. In this case, if such modifications and variations of the embodiments of the present disclosure fall within the scope of claims and their equivalents, the present disclosure intends to include these modifications and variations.

1. A display substrate, comprising:
a base substrate;
a low temperature poly-silicon thin film transistor located on the base substrate and comprising a first active layer and a first gate electrode disposed in a stacked manner on the base substrate;
an oxide thin film transistor located on the base substrate and comprising a second active layer located on a side of a layer with the first gate electrode facing away from the base substrate;
a first gate insulating layer located between the first active layer and the layer with the first gate electrode and comprising a hydrogen-containing insulating layer; and
a first interlayer insulating layer located between the layer with the first gate electrode and the second active layer and comprising a hydrogen blocking material layer.

2. The display substrate according to claim 1, wherein the first gate insulating layer comprises: a silicon oxide layer, and a silicon nitride layer located between the silicon oxide layer and the layer with the first gate electrode.

3. The display substrate according to claim 1, wherein the first interlayer insulating layer comprises a silicon oxide layer.

4. The display substrate according to claim 3, further comprising a metal portion disposed on the same layer as the first gate electrode; wherein
an overlap area of an orthographic projection of the metal portion on the base substrate and an orthographic projection of the first active layer on the base substrate is S1, and an overlap area of the orthographic projection of the metal portion on the base substrate and an orthographic projection of the second active layer on the base substrate is S2, wherein S2 is greater than S1.

5. The display substrate according to claim 1, wherein the first interlayer insulating layer comprises: a first silicon oxide layer and a second silicon oxide layer disposed in a stacked manner.

6. The display substrate according to claim 5, further comprising: a metal portion located between the first silicon oxide layer and the second silicon oxide layer; wherein
an overlap area of an orthographic projection of the metal portion on the base substrate and an orthographic projection of the first active layer on the base substrate is S1, and an overlap area of the orthographic projection of the metal portion on the base substrate and an orthographic projection of the second active layer on the base substrate is S2, wherein S2 is greater than S1.

7. The display substrate according to claim 4, wherein the metal portion is a second gate electrode of the oxide thin film transistor.

8. The display substrate according to claim 4, wherein the metal portion is a light shielding layer, wherein an orthographic projection of the light shielding layer on the base substrate covers the orthographic projection of the second active layer on the base substrate.

9. The display substrate according to claim 1, wherein the low temperature poly-silicon thin film transistor further comprises: a first source electrode and a first drain electrode located on a side of the layer with the first gate electrode facing away from the first active layer, and the first source electrode and the first drain electrode are electrically connected with the first active layer respectively; and
the oxide thin film transistor further comprises: a third gate electrode located on a side of the second active layer facing away from the first interlayer insulating layer, and a second source electrode and a second drain electrode located on a side of a layer with the third gate electrode facing away from the second active layer; wherein the second source electrode and the second drain electrode are electrically connected with the second active layer respectively, and the second source electrode and the second drain electrode are disposed on the same layer as the first source electrode and the first drain electrode.

10. The display substrate according to claim 9, further comprising: a second gate insulating layer located between the second active layer and the layer with the third gate electrode and formed from silicon oxide, and a second interlayer insulating layer located between the layer with the third gate electrode and a layer with the second source electrode and the second drain electrode.

11. The display substrate according to claim 10, wherein the second interlayer insulating layer comprises a silicon oxide layer, or comprises a silicon oxide layer and a silicon nitride layer arranged in a stacked manner.

12. The display substrate according to claim 1, further comprising: a barrier layer located between the base substrate and the first active layer, and a buffer layer located between the barrier layer and the first active layer.

13. A display panel, comprising a display substrate according to, wherein the display substrate comprises:
a base substrate;
a low temperature poly-silicon thin film transistor located on the base substrate and comprising a first active layer and a first gate electrode disposed in a stacked manner on the base substrate;
an oxide thin film transistor located on the base substrate and comprising a second active layer located on a side of a layer with the first gate electrode facing away from the base substrate;
a first gate insulating layer located between the first active layer and the layer with the first gate electrode and comprising a hydrogen-containing insulating layer; and
a first interlayer insulating layer located between the layer with the first gate electrode and the second active layer and comprising a hydrogen blocking material layer.

14. A display device, comprising a display panel comprising a display substrate, wherein the display substrate comprises:
a base substrate;
a low temperature poly-silicon thin film transistor located on the base substrate and comprising a first active layer and a first gate electrode disposed in a stacked manner on the base substrate;
an oxide thin film transistor located on the base substrate and comprising a second active layer located on a side of a layer with the first gate electrode facing away from the base substrate;
a first gate insulating layer located between the first active layer and the layer with the first gate electrode and comprising a hydrogen-containing insulating layer; and
a first interlayer insulating layer located between the layer with the first gate electrode and the second active layer and comprising a hydrogen blocking material layer.

15. The display substrate according to claim 6, wherein the metal portion is a second gate electrode of the oxide thin film transistor.

16. The display substrate according to claim 6, wherein the metal portion is a light shielding layer, wherein an orthographic projection of the light shielding layer on the base substrate covers the orthographic projection of the second active layer on the base substrate.
